(19) United States
(12) Patent Application Publication
(10) Pub. No.: US 2007/0087227 A1
(43) Pub. Date: Apr. 19, 2007

(54) Granular magnetic recording media with improved corrosion resistance by cap layer + pre-covercoat etching

(75) Inventors: Xiaoding Ma, Fremont, CA (US); Tom P. Nolan, Fremont, CA (US); Raj Thangaraj, Fremont, CA (US); Michael J. Stirniman, Fremont, CA (US); Samuel D. Harkness IV, Berkeley, CA (US); Huan Tang, Los Altos, CA (US); Jing Gui, Fremont, CA (US); Joel R. Weiss, Fremont, CA (US); Gary C. Rauch, Boulder, CO (US)

Correspondence Address: SEAGATE TECHNOLOGY LLC;c/o MCDERMOTT WILL & EMERY LLP, 600 13TH STREET, NW, WASHINGTON, DC, 20005-3096, US

(73) Assignee: SEAGATE TECHNOLOGY LLC

(21) Appl. No.: 11/249,469

(22) Filed: Oct. 14, 2005

(51) Int. Cl. G11B 5/65; C23C 14/00

(52) U.S. Cl. 428/833.1; 428/833.2; 204/298.31

(57) ABSTRACT

A granular magnetic recording medium comprises a non-magnetic substrate having a surface, a layer stack on the substrate surface, including an outermost granular magnetic recording layer, a cap layer on the granular magnetic recording layer, having a sputter-etched outer surface, and a protective overcoat layer on the sputter-etched outer surface of the cap layer.

### FIELD OF THE DISCLOSURE

The present disclosure relates to methods for improving the corrosion resistance of thin film magnetic recording media and to magnetic recording media obtained thereby. The disclosure has particular utility in the manufacture of high areal recording density media, e.g., hard disks, utilizing granular-type magnetic recording layers.

### BACKGROUND DISCUSSION

Magnetic media are widely used in various applications, particularly in the computer industry for data/information storage and retrieval applications, typically in disk form, and efforts are continually made with the aim of increasing the areal recording density, i.e., bit density of the magnetic media. Conventional thin film thin-film type magnetic media, wherein a fine-grained polycrystalline magnetic alloy layer serves as the active recording layer, are generally classified as “longitudinal” or “perpendicular”, depending upon the orientation of the magnetic domains of the grains of magnetic material.

A portion of a conventional longitudinal recording, thin-film, hard disk-type magnetic recording medium 1 commonly employed in computer-related applications is schematically illustrated in FIG. 1 in simplified cross-sectional view, and comprises a substantially rigid, non-magnetic metal substrate 10, typically of aluminum (Al) or an aluminum-based alloy, such as an aluminum-magnesium (Al—Mg) alloy, having sequentially deposited or otherwise formed on a surface 10A thereof a plating layer 11, such as of amorphous nickel-phosphorus (Ni—P); a seed layer 12A of an amorphous or fine-grained material, e.g., a nickel-aluminum (Ni—Al) or chromium-titanium (Cr—Ti) alloy; a polycrystalline underlayer 12B, typically of Cr or a Cr-based alloy; a magnetic recording layer 13, e.g., of a cobalt (Co)-based alloy with one or more of platinum (Pt), Cr, boron (B), etc.; a protective overcoat layer 14, typically containing carbon (C), e.g., diamond-like carbon (“DLC”); and a lubricant topcoat layer 15, e.g., of a perfluoropolyether. Each of layers 11-14 may be deposited by suitable physical vapor deposition (“PVD”) techniques, such as sputtering, and layer 15 is typically deposited by dipping or spraying.

In operation of medium 1, the magnetic layer 13 is locally magnetized by a write transducer, or write “head”, to record and thereby store data/information therein. The write transducer or head creates a highly concentrated magnetic field which alternates direction based on the bits of information to be stored. When the local magnetic field produced by the write transducer is greater than the coercivity of the material of the recording medium layer 13, the grains of the polycrystalline material at that location are magnetized. The grains retain their magnetization after the magnetic field applied thereto by the write transducer is removed. The direction of the magnetization matches the direction of the applied magnetic field. The magnetization of the recording medium layer 13 can subsequently produce an electrical response in a read transducer, or read “head”, allowing the stored information to be read.

So-called “perpendicular” recording media have been found to be superior to the more conventional “longitudinal” media in achieving very high bit densities. In perpendicular magnetic recording media, residual magnetization is formed in a direction perpendicular to the surface of the magnetic medium, typically a layer of a magnetic material on a suitable substrate. Very high linear recording densities are obtainable by utilizing a “single-pole” magnetic transducer or “head” with such perpendicular magnetic media.

Efficient, high bit density recording utilizing a perpendicular magnetic medium requires interposition of a relatively thick (as compared with the magnetic recording layer), magnetically “soft” underlayer (“SUL”) layer, i.e., a magnetic layer having a relatively low coercivity below about 1 kOe, such as of a NiFe alloy (Permalloy), between the non-magnetic substrate, e.g., of glass, aluminum (Al) or an Al-based alloy, and the magnetically “hard” recording layer having relatively high coercivity, typically about 3-8 kOe, e.g., of a cobalt-based alloy (e.g., a Co—Cr alloy such as CoCrPtB) having perpendicular anisotropy. The magnetically soft underlayer serves to guide magnetic flux emanating from the head through the hard, perpendicular magnetic recording layer.

A typical conventional perpendicular recording system 20 utilizing a vertically oriented magnetic medium 21 with a relatively thick soft magnetic underlayer, a relatively thin hard magnetic recording layer, and a single-pole head, is illustrated in FIG. 2, wherein reference numerals 10, 11, 4, 5, and 6, respectively, indicate a non-magnetic substrate, an adhesion layer (optional), a soft magnetic underlayer, at least one non-magnetic interlayer, and at least one perpendicular hard magnetic recording layer. Reference numerals 7 and 8, respectively, indicate the single and auxiliary poles of a single-pole magnetic transducer head 6. The relatively thin interlayer 5 (also referred to as an “intermediate” layer), comprised of one or more layers of non-magnetic materials, serves to (1) prevent magnetic interaction between the soft underlayer 4 and the at least one hard recording layer 6 and (2) promote desired microstructural and magnetic properties of the at least one hard recording layer.

As shown by the arrows in the figure indicating the path of the magnetic flux φ, flux φ is seen as emanating from single pole, 7 of single-pole magnetic transducer head 6, entering and passing through the at least one vertically oriented, hard magnetic recording layer 5 in the region below single pole 7, entering and traveling within soft magnetic underlayer 3 for a distance, and then exiting therefrom and passing through the at least one perpendicular hard magnetic recording layer 6 in the region below auxiliary pole 8 of single-pole magnetic transducer head 6. The direction of movement of perpendicular magnetic medium 21 past transducer head 6 is indicated in the figure by the arrow above medium 21.

With continued reference to FIG. 2, vertical lines 9 indicate grain boundaries of polycrystalline layers 5 and 6 of the layer stack constituting medium 21. Magnetically hard main recording layer 6 is formed on interlayer 5, and while the grains of each polycrystalline layer may be of differing widths (as measured in a horizontal direction) represented by a grain size distribution, they are generally in vertical registry (i.e., vertically “correlated” or aligned).

Completing the layer stack is a protective overcoat layer 14, such as of a diamond-like carbon (DLC), formed over hard magnetic layer 6, and a lubricant topcoat layer 15, such as of a perfluoropolyethylene material, formed over the protective overcoat layer.

Substrate 10 is typically disk-shaped and comprised of a non-magnetic metal or alloy, e.g., Al or an Al-based alloy, such as Al—Mg having an Ni—P plating layer on the deposition surface thereof, or substrate 10 is comprised of a suitable glass, ceramic, glass-ceramic, polymeric material, or a composite or laminate of these materials. Optional adhesion layer 11, if present, may comprise an up to about 30 Å thick layer of a material such as Ti or a Ti alloy. Soft magnetic underlayer 4 is typically comprised of an about 500 to about 4,000 Å thick layer of a soft magnetic material selected from the group consisting of Ni, NiFe (Permalloy), Co, CoZr, CoZrCr, CoZrNb, CoFeZrNb, CoFe, Fe, FeN, FeSiAl, FeSiAlN, FeCoB, FeCoC, etc. Interlayer 5 typically comprises an up to about 300 Å thick layer or layers of non-magnetic material(s), such as Ru, TiCr, Ru/CoCr₃₇Pt₆, RuCr/CoCrPt, etc.; and the at least one hard magnetic layer 6 is typically comprised of an about 100 to about 250 Å thick layer(s) of Co-based alloy(s) including one or more elements selected from the group consisting of Cr, Fe, Ta, Ni, Mo, Pt, V, Nb, Ge, B, and Pd, iron nitrides or oxides, or a (CoX/Pd or Pt)ₙ multilayer magnetic superlattice structure, where n is an integer from about 10 to about 25. Each of the alternating, thin layers of Co-based magnetic alloy of the superlattice is from about 2 to about 3.5 Å thick, X is an element selected from the group consisting of Cr, Ta, B, Mo, Pt, W, and Fe, and each of the alternating thin, non-magnetic layers of Pd or Pt is up to about 10 Å thick. Each type of hard magnetic recording layer material has perpendicular anisotropy arising from magneto-crystalline anisotropy (1^{st} type) and/or interfacial anisotropy (2^{nd} type).

A currently employed way of classifying magnetic recording media is on the basis by which the magnetic grains of the recording layer are mutually separated, i.e., segregated, in order to physically and magnetically de-couple the grains and provide improved media performance characteristics. According to this classification scheme, magnetic media with Co-based alloy magnetic recording layers (e.g., CoCr alloys) are classified into two distinct types: (1) a first type, wherein segregation of the grains occurs by diffusion of Cr atoms of the magnetic layer to the grain boundaries of the layer to form Cr-rich grain boundaries, which diffusion process requires heating of the media substrate during formation (deposition) of the magnetic layer; and (2) a second type, wherein segregation of the grains occurs by formation of oxides, nitrides, and/or carbides at the boundaries between adjacent magnetic grains to form so-called “granular” media, which oxides, nitrides, and/or carbides may be formed by introducing a minor amount of at least one reactive gas containing oxygen, nitrogen, and/or carbon atoms (e.g. O₂, N₂, CO₂, etc.) to the inert gas (e.g., Ar) atmosphere during sputter deposition of the Co alloy-based magnetic layer.

Magnetic recording media with granular magnetic recording layers possess great potential for achieving ultra-high areal recording densities. As indicated above, current methodology for manufacturing granular-type magnetic recording media involves reactive sputtering of the magnetic recording layer in a reactive gas-containing atmosphere, e.g., an O₂ and/or N₂ atmosphere, in order to incorporate oxides and/or nitrides therein and achieve smaller and more isolated magnetic grains. However, magnetic films formed according to such methodology typically are very porous and rough-surfaced compared to media formed utilizing conventional techniques. Corrosion and environmental testing of granular recording media indicate very poor resistance to corrosion and environmental influences and even relatively thick carbon-based protective overcoats, e.g., ˜40 Å thick, provide inadequate resistance to corrosion and environmental attack. Studies have determined that the root cause of the poor corrosion performance of granular magnetic recording media is incomplete coverage of the surface of the magnetic recording layer by the protective overcoat (typically carbon), due to high nano-scale roughness, porous oxide grain boundaries, and/or poor carbon adhesion to oxides.

Previous studies which are disclosed in commonly assigned, co-pending application Ser. No. 10/776,223, filed Feb. 12, 2004, the entire disclosure of which is incorporated herein by reference, demonstrated that corrosion performance of granular magnetic recording media may be improved by ion etching (e.g., sputter etching) the surface of the granular magnetic recording layer(s) prior to deposition thereon of the carbon protective overcoat layer. However, a disadvantage associated with such methodology is that since the magnetic recording layer(s) is (are) subject to direct ion etching, magnetic material is removed, and as a result, the magnetic properties are altered.

In view of the foregoing, there exists a clear need for methodology for manufacturing high areal recording density, high performance granular-type longitudinal and perpendicular magnetic recording media with improved corrosion resistance and optimal magnetic properties, which methodology is fully compatible with the requirements of high product throughput, cost-effective, automated manufacture of such high performance magnetic recording media.

The present invention, therefore, addresses and solves the above-described problems, drawbacks, and disadvantages associated with the above-described methodology for the manufacture of high performance magnetic recording media comprising granular-type magnetic recording layers, while maintaining full compatibility with all aspects of automated manufacture of magnetic recording media.

### SUMMARY OF THE DISCLOSURE

An advantage of the present disclosure is improved methods of manufacturing granular longitudinal and perpendicular granular magnetic recording media with enhanced corrosion and environmental resistance.

Another advantage of the present disclosure is improved granular longitudinal and perpendicular magnetic recording media with enhanced corrosion and environmental resistance.

Additional advantages and other features of the present disclosure will be set forth in the description which follows and in part will become apparent to those having ordinary skill in the art upon examination of the following or may be learned from the practice of the present invention. The advantages of the present invention may be realized and obtained as particularly pointed out in the appended claims.

According to an aspect of the present invention, the foregoing and other advantages are obtained in part by a method of manufacturing granular magnetic recording media, comprising sequential steps of:

(a) providing a non-magnetic substrate including a surface;

(b) forming a layer stack on the surface of the substrate, the layer stack including an outermost granular magnetic recording layer having an exposed surface;

(c) forming a layer of a cap material over the exposed surface of the granular magnetic recording layer, the cap layer having an exposed surface;

(d) etching the exposed surface of the cap layer to remove at least a portion of the thickness thereof and form a treated surface; and

(e) forming a protective overcoat layer on the treated surface.

According to embodiments of the present methodology, step (b) comprises forming a layer stack including an outermost perpendicular magnetic recording layer or an outermost longitudinal magnetic recording layer; step (c) comprises forming a metallic cap layer, i.e., an amorphous or crystalline metallic cap layer of thickness from about 5 Å to about 100 Å, from a material selected from the group consisting of: Cr-containing alloys, Ta-containing alloys, and Nb-containing alloys; step (d) comprises ion etching the exposed surface of the cap layer, preferably by sputter etching with ions of an inert gas (e.g., Ar ions) to leave a thickness from about 0 to about 50 Å; and step (e) comprises forming a carbon (C)-containing protective overcoat layer at a thickness from about 15 to about 50 Å, preferably a diamond-like (DLC) protective overcoat layer, by means of ion beam deposition (IBD), plasma-enhanced chemical vapor deposition (PECVD), or filtered cathodic arc deposition (filtered CAD).

Preferred embodiments of the disclosure include those wherein step (c) comprises forming a layer of an etch-resistant material on the exposed surface of the granular magnetic recording layer and then forming the cap layer on the layer of etch-resistant material, and step (d) comprises etching substantially the entire thickness of the cap layer. Preferably, step (c) comprises forming a layer of a sputter etch-resistant material, e.g., a layer of amorphous carbon at a thickness from about 5 Å to about 25 Å.

In accordance with embodiments of the present methodology, step (b) comprises forming the layer stack as including a granular Co-based alloy magnetic recording layer comprised of a CoPtX alloy, where X=at least one element or material selected from the group consisting of: Cr, Ta, B, Mo, V, Nb, W, Zr, Re, Ru, Cu, Ag, Hf, Ir, Y, O, Si, Ti, N, P, Ni, SiO₂, SiO, Si₃N₄, Al₂O₃, AlN, TiO, TiO₂, TiOₓ, TiN, TiC, Ta₂O₅, NiO, and CoO, and wherein Co-containing magnetic grains are segregated by grain boundaries comprising at least one of oxides, nitrides, and carbides.

Another aspect of the present invention is granular magnetic recording media manufactured by the above-recited process.

Still another aspect of the present invention is a granular magnetic recording medium, comprising:

(a) a non-magnetic substrate having a surface;

(b) a layer stack on the substrate surface, the layer stack including an outermost granular magnetic recording layer;

(c) a cap layer on the granular magnetic recording layer, the cap layer having a sputter-etched outer surface; and

(d) a protective overcoat layer on the sputter-etched outer surface of the cap layer.

According to embodiments of the disclosure, the granular magnetic recording layer is a perpendicular magnetic recording layer or a longitudinal magnetic recording layer; the cap layer includes an amorphous or crystalline metallic layer comprised of a material selected from the group consisting of: Cr-containing alloys, Ta-containing alloys, and Nb-containing alloys; the cap layer further comprises a layer of a sputter etch-resistant material intermediate the granular magnetic recording layer and the layer of metallic material, e.g., a layer of amorphous carbon; the granular Co-based alloy magnetic recording layer comprises a CoPtX alloy, where X=at least one element or material selected from the group consisting of: Cr, Ta, B, Mo, V, Nb, W, Zr, Re, Ru, Cu, Ag, Hf. Ir, Y, O, Si, Ti, N, P, Ni, SiO₂, SiO, Si₃N₄, Al₂O₃, AlN, TiO, TiO₂, TiOₓ, TiN, TiC, Ta₂O₅, NiO, and CoO, and wherein Co-containing magnetic grains are segregated by grain boundaries comprising at least one of oxides, nitrides, and carbides; the protective overcoat layer comprises a carbon (C)-containing material.

Additional advantages and aspects of the disclosure will become readily apparent to those skilled in the art from the following detailed description, wherein embodiments of the present methodology are shown and described, simply by way of illustration of the best mode contemplated for practicing the present invention. As will be described, the present disclosure is capable of other and different embodiments, and its several details are susceptible of modification in various obvious respects, all without departing from the spirit of the present invention. Accordingly, the drawings and description are to be regarded as illustrative in nature, and not as limitative.

### BRIEF DESCRIPTION OF THE DRAWINGS

The following detailed description of the embodiments of the present disclosure can best be understood when read in conjunction with the following drawings, in which the various features (e.g., layers) are not necessarily drawn to scale but rather are drawn as to best illustrate the pertinent features, wherein:

FIG. 1 schematically illustrates, in simplified cross-sectional view, a portion of a conventional thin film longitudinal magnetic recording medium;

FIG. 2 schematically illustrates, in simplified cross-sectional view, a portion of a magnetic recording storage, and retrieval system comprised of a perpendicular magnetic recording medium and a single pole transducer head;

FIG. 3 schematically illustrates, in simplified cross-sectional view, a series of process steps according to an embodiment of the disclosed methodology;

FIG. 4 is a graph for illustrating the variation of magnetic properties of cells with granular magnetic films as a function of cap layer thickness and performance of etching treatment according to the instant disclosure;

FIG. 5 is a graph for illustrating the dependence of the corrosion resistance of the cells with granular magnetic films as a function of cap layer thickness and performance of etching treatment according to the disclosure; and

FIG. 6 schematically illustrates, in simplified cross-sectional view, a series of process steps according to another embodiment of the disclosed methodology.

### DESCRIPTION OF THE DISCLOSURE

The present invention addresses and solves problems, disadvantages, and drawbacks associated with the poor corrosion and environmental resistance of granular longitudinal and perpendicular magnetic recording media fabricated according to prior methodologies, and is based upon recent investigations by the present inventors which have determined that the underlying cause of the poor corrosion performance of such media is attributable, inter alia, to incomplete surface coverage of the protective overcoat layer (typically of a DLC material) arising from increased nano-scale roughness of the granular magnetic recording layer relative to that of several other types magnetic recording layers, the presence of porous grain boundaries, and poor adhesion of the protective overcoat layer at the grain boundaries.

The present invention is further based upon recognition by the present inventors that the aforementioned problems of poor corrosion and environmental resistance of granular magnetic recording layers can be mitigated, if not entirely eliminated, by performing a suitable treatment of the surface thereof prior to formation thereon of the protective overcoat layer. More specifically, the inventors have determined that the corrosion resistance of such media may be significantly improved by forming a thin, protective “cap” layer over the rough and porous surface of the granular magnetic recording layer upon completion of its formation, and then etching the surface of the cap layer to remove at least a portion of the thickness thereof and provide a relatively smooth, continuous surface for deposition of the protective overcoat layer thereon. Preferably, the etching process involves sputter etching with ions of an inert gas, e.g., Ar ions, for a sufficient interval to effect removal of at least a surface portion of the cap layer. An advantage afforded by provision of the cap layer according to the instant methodology vis-à-vis the previously disclosed methodology is that the magnetic layer(s) underlying the cap layer are effectively shielded from etching, hence damage, by the ion bombardment sputter etching process, and disadvantageous alteration of the magnetic properties and characteristics of the as-deposited, optimized magnetic recording layer(s) is effectively eliminated while maintaining the improved corrosion resistance of the media provided by etching of the media surface prior to deposition of the protective overcoat layer.

According to a further embodiment of the present invention, an additional layer, i.e., a thin “etch-stop” layer comprised of a material which is more resistant to the particular etching process utilized, e.g., a thin layer of a sputter etch-resistant material, is provided between the as-deposited granular magnetic recording layer and the cap layer in order to minimize the likelihood of complete removal of the cap layer during the etching process disadvantageously resulting in etching of the magnetic layer and alteration of the magnetic properties and characteristics thereof.

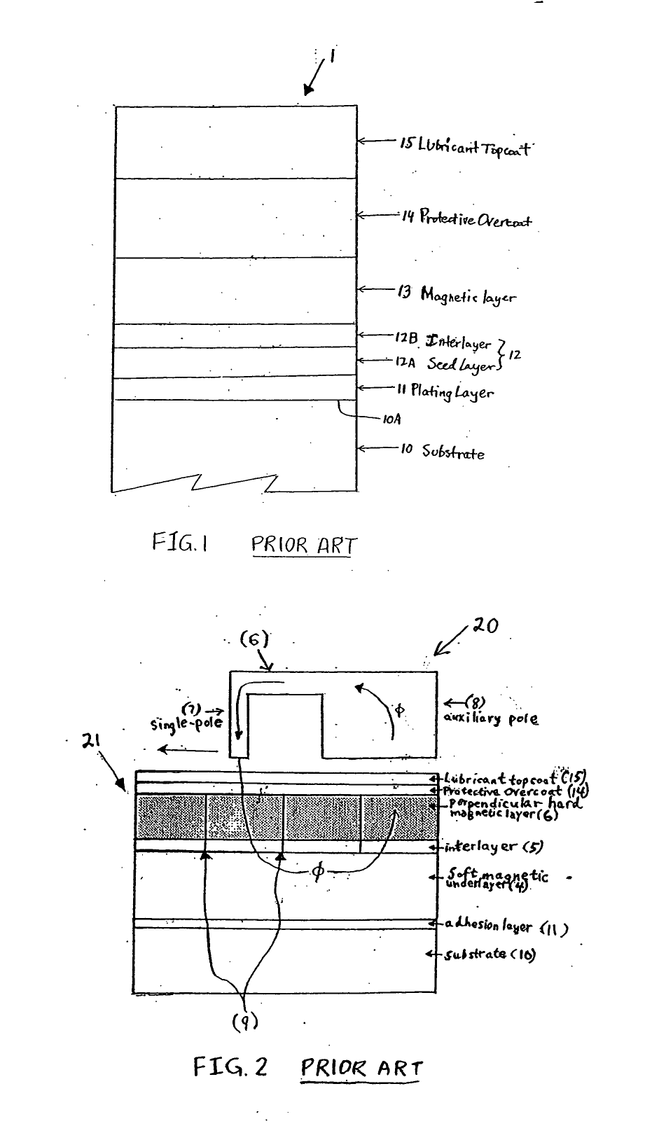

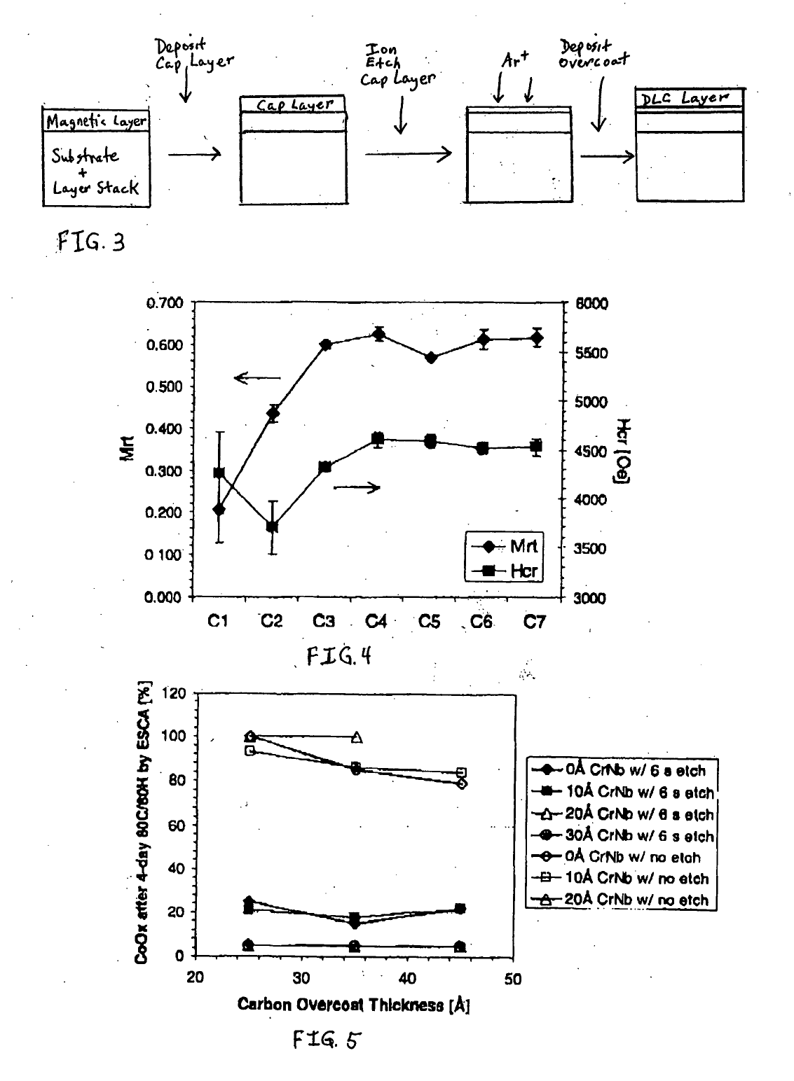

Referring now to FIG. 3, a series of process steps embodying the principles of the disclosure will now be described in detail by reference to the following illustrative, but not limitative, example of the instantly disclosed methodology. According to an initial step of the methodology, a magnetic recording medium with a layer stack similar to that shown in FIG. 1 and described supra is provided, and typically includes a disk-shaped non-magnetic substrate comprised of a non-magnetic material selected from the group consisting of: Al, NiP-plated Al, Al—Mg alloys, other Al-based alloys, other non-magnetic metals, other non-magnetic alloys, glass, ceramics, polymers, glass-ceramics, and composites and/or laminates of the aforementioned materials and a layer stack formed thereon which includes an outermost granular longitudinal or perpendicular magnetic recording film or layer. The latter is illustratively (but not limitatively) comprised of a CoPtX alloy, where X=at least one element or material selected from the group consisting of: Cr, Ta, B, Mo, V, Nb, W, Zr, Re, Ru, Cu, Ag, Hf, Ir, Y, O, Si, Ti, N, P, Ni, SiO₂, SiO, Si₃N₄, Al₂O₃, AlN, TiO, TiO₂, TiOₓ, TiN, TiC, Ta₂O₅, NiO, and CoO, and wherein Co-containing magnetic grains are segregated by grain boundaries comprising at least one of oxides, nitrides, and carbides formed e.g., by reactive sputtering.

Still referring to FIG. 3, in the next step according to the methodology, a thin cap layer is formed over the exposed uppermost surface of the granular magnetic recording layer by any convenient thin film deposition technique, e.g., sputtering. According to the disclosure, the cap layer preferably is comprised of a metallic material, i.e., an amorphous or crystalline metallic layer of thickness from about 5 Å to about 100 Å, and may be formed of a single metal element or a multi-element alloy. Suitable elemental and alloy materials for use as the cap layer according to the disclosure include those selected from the group consisting of: Cr-containing alloys, Ta-containing alloys, and Nb-containing alloys.

In the next step according to the disclosure, illustrated in FIG. 3, the cap layer is subjected to an etching process for removing at least a portion of the thickness thereof. Suitable etching techniques for controllable removal of a desired thickness of the cap layer include ion etching, preferably sputter etching with ions of an inert gas (e.g., Ar ions). According to the methodology, a portion of the thickness of the cap layer may remain after ion etching or the entire thickness thereof may be removed. Thus, the thickness of the cap layer after ion etching may range from about 0 to about 50 Å.

With continued reference to FIG. 3, in the next step according to the disclosure, a protective overcoat layer, typically a carbon (C)-containing protective overcoat layer, is formed on the exposed surface of the remaining cap layer or on the exposed surface of the granular magnetic recording layer, as by any suitable technique. Preferably, the protective overcoat layer comprises an about 15 to about 50 Å thick layer of diamond-like carbon (DLC) formed by means of ion beam deposition (IBD), plasma-enhanced chemical vapor deposition (PECVD), or filtered cathodic arc deposition (filtered CAD).

The utility of the above-described methodology will now be described with reference to the following illustrative, but not limitative, example.

### EXAMPLE

A group of disc-shaped cells each with a granular magnetic film and an overlying CrNb cap layer were fabricated on non-magnetic substrates. The thickness of the CrNb cap layer was varied from 0 to 30 Å in 10 Å increments and some of the cells were subjected to sputter etching for 6 sec. in an NCT station with Ar gas flow at 40 sccm, anode voltage 90 V, and 120 V substrate bias. Following sputter etching, the cells were coated with a 25 Å, 35 Å, or 45 Å thick IBD DLC protective overcoat layer utilizing acetylene (C₂H₂) coating material gas. For comparison purposes, cells without sputter etch processing of the cap layer were also prepared. A description of each of the cells and treatment thereof is summarized in Table I below.

TABLE I

| Cell No. | CrNb thickness, Å | Etch | Carbon thickness, Å |
|---|---|---|---|
| C1 | 0 | Yes | 25, 35, 45 |
| C2 | 10 | Yes | 25, 35, 45 |
| C3 | 20 | Yes | 25, 35, 45 |
| C4 | 30 | Yes | 25, 35, 45 |
| C5 (Control Cell) | 0 | No | 25, 35, 45 |
| C6 | 10 | No | 25, 35, 45 |
| C7 | 20 | No | 25, 35, 45 |

Referring to FIG. 4, shown therein is a graph illustrating the variation of magnetic properties of the above cells (as measured by RDM) with granular magnetic films as a function of cap layer initial thickness and whether the cells were subjected to etching treatment according to the disclosed methodology. As is evident from FIG. 4, when the CrNb cap layer initial thickness is less than 20 Å, Mrt and H_{cr} are lower than in the case of control cell C5, indicating that the 6 sec. Ar ion sputter etch removed the entire thickness of the CrNb cap layer as well as some amount of the underlying granular magnetic recording layer. By contrast, when the CrNb cap layer initial thickness is 20 Å or greater, some amount of the CrNb cap layer remained after the 6 sec. Ar ion etch. As a consequence, the underlying granular magnetic layer was unaffected by the ion etch, and the post-etch Mrt and H_{cr} values are close to those of the control cell C5.

Adverting to FIG. 5, shown therein is a graph illustrating the dependence of the corrosion resistance of the above cells C1-C7 as a function of cap layer initial thickness and whether an etching treatment according to the disclosure was performed. Corrosion resistance was determined by maintaining the cells in an environmental chamber at 80° C./80% RH for 4 days and the growth of CoOₓ (derived from the Co alloy-based granular magnetic recording layer) thereon due to corrosion measured by ESCA. As is evident from FIG. 5, cells which received the Ar ion sputter etch processing exhibited much lower CoOₓ % than cells which did not receive the Ar ion sputter etch processing. Of the cells which received the Ar ion sputter etch processing, those with 20 Å and 30 Å CrNb cap layer initial thicknesses exhibited virtually no CoOₓ growth after the environmental exposure.

Thus, by controlling the cap layer initial thickness and etch process, the instant methodology enables manufacture of granular magnetic recording media with significantly improved corrosion resistance and without incurring degradation of the properties/characteristics of the magnetic recording layer.

Ideally, the cap layer initial thickness should be reduced by the etching process to as thin as possible in order to reduce the spacing between the read/write transducer head and the surface of the magnetic recording layer. However, obtainment of minimal cap layer post-etching thicknesses can disadvantageously result in damage of the underlying granular magnetic recording layer(s) due to ion bombardment and etching thereof, resulting in degradation of the signal-to-media-noise ratio (SMNR).

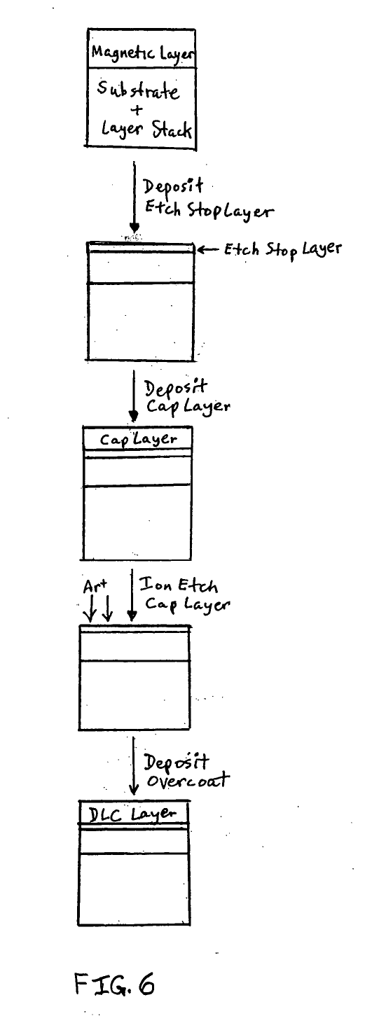

Therefore, according to another aspect of the present methodology, shown in simplified, schematic cross-section in FIG. 6, a very thin layer of a substantially etch-resistant material is interposed between the granular magnetic recording layer and the cap layer as an “etch-stop” layer. According to an embodiment of the present disclosure involving such etch-stop layer, use is made of the relative resistance of amorphous carbon to sputter etching by Ar ions compared to the metallic cap layer material. More specifically, the material removal rate of amorphous carbon under typical sputter etch processing utilizing Ar ions is on the order of about 0.05 nm/sec., which rate is substantially less than the Ar sputter etch rates of metallic layers under substantially similar conditions, i.e., ˜0.3-˜0.5 nm/sec. Thus, placement of a thin layer of amorphous carbon (e.g., from about 5 Å to about 25 Å thick) intermediate the granular perpendicular magnetic recording layer(s) and the cap layer facilitates maximum removal thereof for minimizing transducer head-magnetic layer spacing while preventing damage and etching of the magnetic layer during etching.

It should be noted that the above-described embodiments of the instantly disclosed methodology are merely illustrative, and not limitative, of the advantageous results afforded by the invention. Specifically, the methodology is not limited to use with the illustrated CoPtX magnetic alloys, but rather is useful in providing enhanced corrosion and environmental resistance of recording media comprising all manner of granular longitudinal or perpendicular magnetic recording layers having surfaces with nano-scale roughness and porosity. Similarly, the ion etching treatment of the disclosure is not limited to use with the illustrated Ar ions, and satisfactory ion etching may be performed with numerous other inert ion species, including, for example, He, Kr, Xe, and Ne ions. In addition, specific process conditions for performing the ion etching are readily determined for use in a particular application of the disclosed methodology, including selection of the rate of flow of the inert gas, substrate bias voltage, ion etching interval, ion energy, and etching rate. For example, suitable ranges of substrate bias voltages, ion energies, and etching rates are 0-300 V, 10-400 eV, and 0.1-20 Å/sec., respectively. Lastly, the protective overcoat layer is not limited to IBD DLC but rather all manner of protective overcoat materials and deposition methods therefore may be utilized.

In the previous description, numerous specific details are set forth, such as specific materials, structures, processes, etc., in order to provide a better understanding of the present invention. However, the present invention can be practiced without resorting to the details specifically set forth. In other instances, well-known processing materials and techniques have not been described in detail in order not to unnecessarily obscure the present invention.

Only the preferred embodiments of the present invention and but a few examples of its versatility are shown and described in the present disclosure. It is to be understood that the present invention is capable of use in various other combinations and environments and is susceptible of changes and/or modifications within the scope of the inventive concept as expressed herein.

What is claimed is:

1. A method of manufacturing granular magnetic recording media, comprising sequential steps of:
(a) providing a non-magnetic substrate including a surface;
(b) forming a layer stack on said surface of said substrate, said layer stack including an outermost granular magnetic recording layer having an exposed surface;
(c) forming a layer of a cap material over said exposed surface of said granular magnetic recording layer, said cap layer having an exposed surface;
(d) etching said exposed surface of said cap layer to remove at least a portion of the thickness thereof and form a treated surface; and
(e) forming a protective overcoat layer on said treated surface.

2. The method according to claim 1, wherein:
step (b) comprises forming a layer stack including an outermost longitudinal or perpendicular magnetic recording layer.

3. The method according to claim 1, wherein:
step (c) comprises forming an about 5 Å to about 100 Å amorphous or crystalline metallic cap layer comprising material selected from the group consisting of: Cr-containing alloys, Ta-containing alloys, and Nb-containing alloys.

4. The method according to claim 1, wherein:
step (d) comprises ion etching said exposed surface of said cap layer.

5. The method according to claim 4, wherein:
step (d) comprises sputter etching said exposed surface of said cap layer with inert gas ions.

6. The method according to claim 5, wherein:
step (d) comprises etching said cap layer to leave a thickness thereof from about 0 to about 50 Å.

7. The method according to claim 1, wherein:
step (e) comprises forming a carbon (C)-containing protective overcoat layer.

8. The method according to claim 1, wherein:
step (c) comprises forming a layer of an etch-resistant material on said exposed surface of said granular magnetic recording layer and then forming said cap layer on said layer of etch-resistant material.

9. The method according to claim 8, wherein:
step (d) comprises etching substantially the entire thickness of said cap layer.

10. The method according to claim 8, wherein:
step (c) comprises forming a layer of a sputter etch-resistant material.

11. The method according to claim 10, wherein:
step (c) comprises forming a layer of amorphous carbon as said sputter etch-resistant material.

12. The method according to claim 1, wherein:
step (b) comprises forming said layer stack as including a granular Co-based alloy magnetic recording layer comprised of a CoPtX alloy, where X=at least one element or material selected from the group consisting of: Cr, Ta, B, Mo, V, Nb, W, Zr, Re, Ru, Cu, Ag, Hf, Ir, Y, O, Si, Ti, N, P, Ni, SiO₂, SiO, Si_{3 N}₄, Al₂O₃, AlN, TiO, TiO₂, TiOₓ, TiN, TiC, Ta₂O₅, NiO, and CoO, and wherein Co-containing magnetic grains are segregated by grain boundaries comprising at least one of oxides, nitrides, and carbides.

13. A granular magnetic recording medium manufactured by the process according to claim 1.

14. A granular magnetic recording medium, comprising:
(a) a non-magnetic substrate having a surface;
(b) a layer stack on said substrate surface, said layer stack including an outermost granular magnetic recording layer;
(c) a cap layer on said granular magnetic recording layer, said cap layer having a sputter-etched outer surface; and
(d) a protective overcoat layer on said sputter-etched outer surface of said cap layer.

15. The medium as in claim 14, wherein:
said granular magnetic recording layer is a perpendicular or longitudinal magnetic recording layer.

16. The medium as in claim 14, wherein:
said cap layer includes an amorphous or crystalline metallic layer comprised of a material selected from the group consisting of: Cr-containing alloys, Ta-containing alloys, and Nb-containing alloys.

17. The medium as in claim 14, wherein:
said cap layer further comprises a layer of a sputter etch-resistant material intermediate said granular magnetic recording layer and said layer of metallic material.

18. The medium as in claim 17, wherein:
said layer of sputter etch-resistant material comprises amorphous carbon.

19. The medium as in claim 14, wherein:
said granular Co-based alloy magnetic recording layer comprises a CoPtX alloy, where X=at least one element or material selected from the group consisting of: Cr, Ta, B, Mo, V, Nb, W, Zr, Re, Ru, Cu, Ag, Hf, Ir, Y, O, Si, Ti, N, P, Ni, SiO₂, SiO, Si_{3 N}₄, Al₂O₃, AlN, TiO, TiO₂, TiOₓ, TiN, TiC, Ta₂O₅, NiO, and CoO, and wherein Co-containing magnetic grains are segregated by grain boundaries comprising at least one of oxides, nitrides, and carbides.

20. The medium as in claim 14, wherein:
said protective overcoat layer comprises a carbon (C)-containing material.
